(19) United States
(12) Patent Application Publication
(10) Pub. No.: US 2007/0002342 A1
(43) Pub. Date: Jan. 4, 2007

(54) Systems and methods for evaluating named colors against specified print engines

(75) Inventors: Javier A. Morales, Irondequoit, NY (US); Michael E. Farrell, Williamson, NY (US)

Correspondence Address: OLIFF & BERRIDGE, PLC., P.O. BOX 19928, ALEXANDRIA, VA, 22320, US

(73) Assignee: XEROX CORPORATION, Stamford, CT (US)

(21) Appl. No.: 11/168,918

(22) Filed: Jun. 29, 2005

(51) Int. Cl. G03F 3/08

(52) U.S. Cl. 358/1.9; 358/518

(57) ABSTRACT

Systems and methods of evaluating colors may include a print job source that includes at least one print job, the print job including information of at least one named color. The systems and methods may also include a specified desired state determining device configured to determine a desired state in which the named color in the print job may be reproduced. The systems and methods may also include a desired named color appearance determining device configured to determine a desired named color appearance of the named color in the print job that may be reproduced in the desired state. The systems and methods may also include a specified output device to output the print job. The systems and methods may also include an actual named color appearance determining device configured to determine an actual named color appearance of the named color in the print job that may be reproduced by the output device. Further, the systems and methods may include a difference value determining device configured to determine a difference value between the desired named color appearance and the actual named color appearance of the named color in the print job.

### BACKGROUND

These exemplary systems and methods described herein relate to the field of evaluation of electronic content intended for color printing.

Content evaluations of Page Description Language (PDL) files, for example, color preflights, have been widely used by the imaging industry to serve as a quality assurance tool to inspect the contents of Adobe® PostScript® files to determine whether resources that were required to print a job were included in the file, whether the Open Prepress Interface links were valid, and whether any images included in the file included sufficiently high resolution for good quality printing results. An Adobe® Portable Document Format file is one example of an object-based PDL file that provides easier access to and inventory of the contents of the file in preflighting colors. In addition to revealing the contents of the PDL files, color preflight functionality has evolved to include manual or auto correction capabilities that modify file contents to achieve good quality print results.

Knowledge of the contents of PDL files helps users to identify content that may not be adequately reproduced by a given printing press. For example, in offset lithography printing, named colors may be colors selected from a specified color library such as Pantone® Matching System, FOGRA®, or TOYO®. These named colors are defined as a spot color channel in the source document with an alternative process color approximation definition using solely process colors. The distinction between process colors and spot colors may be useful in various printing applications.

Although process colors may be reproduced by mixing the four primary colors of cyan (C), magenta (M), yellow (Y) and black (K)in a four color press, spot colors may not be adequately produced using the four color press that has four color separations, for example, a printing press having four color CMYK plates or paths. Therefore, in order to reproduce spot colors, special kinds of custom inks may be required. Although each spot color may require an additional, individual color separation, for example, a separate color plate or path in addition to the four CMYK separations, spot colors may provide several benefits.

For example, spot colors may provide a brighter range of colors. Spot colors may also provide special characteristics, such as day-glow or metallic ink, which cannot be produce by mixing CMYK inks. As a result, spot colors may provide increased color flexibility and color reproduction accuracy of a specified color in the print job. Thus, distinguishing spot colors may be beneficial when color precision is important, such as color precision for corporate logos.

By producing and displaying an inventory of the names of all individual spot colors in the PDL file, a viewer of the displayed inventory may determine the number of spot colors existing in the PDL file to ensure that the printing press has the necessary color separations to perform a required print job, for example, six plates for six colors. Since a printing press is set with a predetermined number of color separations, identifying the spot colors of the PDL file allows the viewer to determine which spot colors may not be adequately reproduced because there are not enough color separations in the printing press. Therefore, named spot colors that do not match the reproducible colors of the printing press may be determined.

### SUMMARY

Named color matching, for example, matching spot colors selected from the Pantone® Matching System Color Library, has always been problematic for printing devices because the gamut of the printing device is not large enough to output the entire gamut of the named spot colors. As a result, substantial differences may exist between the named spot colors and the colors reproducible by various print engines because the named spot colors may not match the reproducible colors. Therefore, several methods that attempt to compensate for the color differences have been developed.

For example, some print shops deal with this problem by printing color swatches of the spot colors on specific types of print engines and setting a customer expectation that the printed swatches are actual printed colors that may be expected for the specified print engine. However, distribution of the printed swatches for various types of print engines to every customer may be costly and the printed swatches may not sufficiently cover all types of print engines. Also, manual color inspection is time consuming, costly, and error prone. Further, the printed swatches do not specify which printed colors may be substantially different from the named spot colors, for example, spot colors included in the Pantone® Matching System Color Library.

Another method for certifying the print engine against a specific spot color system, for example, Pantone® Matching System Color Library, may include closely matching all of the named spot colors in that spot color system. For example, Pantone® Matching System certification indicate that a specified print engine has demonstrated the ability to reproduce Pantone® Matching System colors within a defined tolerance. As a result, many of the named spot colors, as well as the CMYK equivalents, may print as accurate approximations of the actual named color.

Although spot color channels may be processed in a manner that enables use of the entire gamut of various print engines, a substantial difference may exist between how the specified print engines output named Pantone® Matching System colors and how those same named spot colors would print on an offset press operating in compliance with Specifications for Web Offset Publications (SWOP). Specifically, print or xerographic engines may include only the four fixed color separations for the CMYK primary colors. However, an offset press with CMYK plus named color capability may include additional color separations for each named spot color. Therefore, if offset press print jobs utilizing spot color separations are reprinted using CMYK only print engines, the color difference may be unacceptable to the print shop's customer.

Although methods for certifying the print engine against specific color libraries may assure the best possible output when printing spot colors, certification does not resolve the gamut problem. Since color preflight is not typically device dependent, it is desirable to determine the suitability of a PDL file for adequate reproduction using a specified device. It is desirable to actually use the information of the PDL file to make corrections or to alert the user if the named spot colors may be capable of adequate reproduction in the specified printing device to enhance preflight capabilities.

Exemplary embodiments may alert designers or application users when named colors in a proofing printer or desired output color space, for example, a SWOP color space, differ from those reproducible in a digital press, for example, Xerox iGen3® Digital Production Press. An inventory may be made of all named colors in a print job and the named spot colors may be converted to values for comparison. Expected named color values for offset presses may be obtained using the appropriate International Color Consortium (ICC) Color Space Profile. Expected named color approximation color values for presses restricted to CMYK printing may be obtained using the ICC Destination Profile of the specific press. If the named colors and the CMYK approximations of the named colors differ more than a given threshold, an alarm may be provided to the user to indicate that these colors will not reproduce as expected. Therefore, exemplary embodiments may compare reproducibility between two profiles or gamuts for general machine characterization.

Exemplary embodiments may include an extension to preflight mechanisms to include warnings about spot colors that will print substantially different from their intended appearance. The user may be able to specify a tolerance for deviation in spot colors. The system may then evaluate each actual spot color against the intended output appearance of the spot color, for example, against Pantone® Matching System coated colors, to determine how that color will be printed in the print engine and assess whether the difference in appearance will be outside the specified tolerance. As a result, a specified digital front end (DFE) controller for the print engine may receive a Adobe® PostScript® or PDF file, spool the file, manage the file, apply color management and use a raster image processor (RIP) to convert the file into a raster that may be fed to a marking device, for example, print engine or plate setter, at rated speeds.

Exemplary embodiments may include a method and mechanism using spot color reproduction deviance information obtained during certification (for example, Pantone® Matching System certification) to identify jobs with potential problems in printing named colors. Although not required, ideally named color preflight may be implemented as part of an automated workflow such as FreeFlow(® Process Manager. In this case, exemplary methods and systems may work as part of a more general preflight evaluation or as an operation in the end-to-end workflow.

Exemplary embodiments may also include alerting designers or printers when named colors may not be produced within some tolerance. For example, output printers may report a delta E deviation of spot colors, for example, as part of Pantone® Matching System certification. The named colors in a print job may be detected and looked up in a table, and the user may be alerted if the delta E or some function thereof exceeds a specified threshold for a particular device.

Exemplary embodiments may also include using information about how well specific spot colors are reproduced to determine whether spot color deviance is outside the desired tolerance.

Exemplary embodiments may involve evaluating colors by obtaining information about a print job, the information including at least one named color, specifying a desired state in which the named color in the print job may be reproduced, determining a desired named color appearance, of the name color in the print job, that may be reproduced in the desired state, specifying an output device to output the print job, determining an actual named color appearance, of the named color in the print job, that may be reproduced by the output device, and determining a difference value between the desired named color appearance and the actual named color appearance of the named color in the print job.

Exemplary embodiments may further include comparing the difference value to a predetermined threshold value, wherein determining the difference value includes determining the actual named color appearance based on at least one characteristic of the output device.

Exemplary embodiments may include determining an output color space in which the named color may be reproduced.

Exemplary embodiments may include converting a named color value of the named color into a neutral named color value of a device neutral color space based on a color profile of the output color space in which the named color may be reproduced.

Exemplary embodiments may include determining a desired named color value of the named color and an actual named color value of the named color.

Exemplary embodiments may include specifying a baseline color space for the desired named color.

Exemplary embodiments may include converting the neutral named color value into a baseline named color value in the baseline color space based on the color profile of the color space in which the named color may be reproduced.

Exemplary embodiments may include determining an output device color profile of a color space of the output device.

Exemplary embodiments may include converting the neutral named color value into an output device named color value in the output device color space based on the output device color profile.

Exemplary embodiments may include calculating the difference value between the desired named color appearance of the named color and the actual named color appearance of the named color.

Exemplary embodiments may include determining color reproduction information of the output device.

Exemplary embodiments may include determining a reproduction color that corresponds to the named color.

Exemplary embodiments may include specifying the reproduction color as the actual named color appearance of the named color.

Exemplary embodiments may include specifying a deviation value associated with the reproduction color as the difference value between the desired named color appearance and the actual named color appearance.

Exemplary embodiments may include determining an existence of a lookup table.

Exemplary embodiments may include obtaining an inventory of all of the named colors.

Exemplary embodiments may include obtaining a named color library that defines all of the named colors.

Exemplary embodiments may include identifying a spot color channel as the named color.

Exemplary embodiments of a system for evaluating colors may include a print job source including at least one print job, the print job including information of at least one named color, a specified desired state determining device configured to determine a desired state in which the named color in the print job may be reproduced, a desired named color appearance determining device configured to determine a desired named color appearance, of the named color in the print job, that may be reproduced in the desired state, a specified output device to output the print job, an actual named color appearance determining device configured to determine an actual named color appearance, of the named color in the print job, that may be reproduced by the output device, and a difference value determining device configured to determine a difference value between the desired named color appearance and the actual named color appearance of the named color in the print job.

Exemplary embodiments may include a printing system including an image output device and the system for evaluating colors.

These and other features are described in or are apparent from the following detailed description.

### BRIEF DESCRIPTION OF THE DRAWINGS

Various exemplary details are described herein, with reference to the following figures, wherein like numerals refer to like parts, and wherein:

FIG. 1 is a flowchart outlining an exemplary method of evaluating colors;

FIG. 2 is a flowchart outlining in greater detail an exemplary method of obtaining information about a print job;

FIG. 3 is a flowchart outlining in greater detail an exemplary method of determining desired named color appearances;

FIG. 4 is a flowchart outlining in greater detail an exemplary method of specifying an output device to output the print job;

FIG. 5 is a flowchart outlining in greater detail an exemplary method of determining actual named color appearances;

FIG. 6 is a flowchart outlining in greater detail an exemplary method of determining difference values between the desired named color appearances and the actual named color appearances of the named color in the print job;

FIGS. 7A-7B is a flowchart outlining in greater detail another exemplary method of determining difference values between the desired named color appearances and the actual named color appearances of the named color in the print job; and

FIG. 8 is a block diagram outlining an exemplary system for evaluating colors.

### DETAILED DESCRIPTION OF EXEMPLARY EMBODIMENTS

The following detailed description is directed to named colors selected from a specified color library, such as a Pantone® Matching System Color Library. However, it should be appreciated that the description is for ease of understanding and familiarity only, and does not exclude named colors selected from other types of specified color libraries, whether known or later developed. In addition, the following terms used herein are defined as set forth below:

“PCS” means a Profile Connection Space that may be an idealized reflective print on a paper that is a perfect, non-selective diffuser, with colorants, for example, dyes or inks, that have a large dynamic range and color gamut. This is essentially a common language for all colors, regardless of color space. Therefore, PCS may be considered an infinite, device neutral coordinate space that effectively serves as the basis for universal translation of colors. PCS refers to the use of a device independent color space such as, for example, an XYZ or L*a*b* space.

“ICC” means an International Color Consortium. The ICC profiles provide the means for converting to and from the PCS.

“Color Space ICC Profile” means color information, of any given color space in terms of the PCS space, that may covert the given color space to and from PCS space.

“Device ICC Profile” means color information, of any given input or output device, for example, camera, scanner, monitor, printer and/or the like, in terms of PCS, that may convert a color space of the given device to and from PCS space.

“Named Color Profile” means color information that may convert the appearance of the named color to and from PCS space.

“Rendering intent” relates to gamut mapping styles defined by the ICC to address the problem of differences among devices in color reproduction gamut. The rendering intent involves a different compromise such as trading off preservation of contrast in order to preserve detail throughout the tonal range. The calorimetric rendering intent enables gamut colors to be reproduced accurately at the expense of out-of-gamut colors.

“Saturation intent” involves compromises such as trading off preservation of hue to preserve the vividness of pure colors.

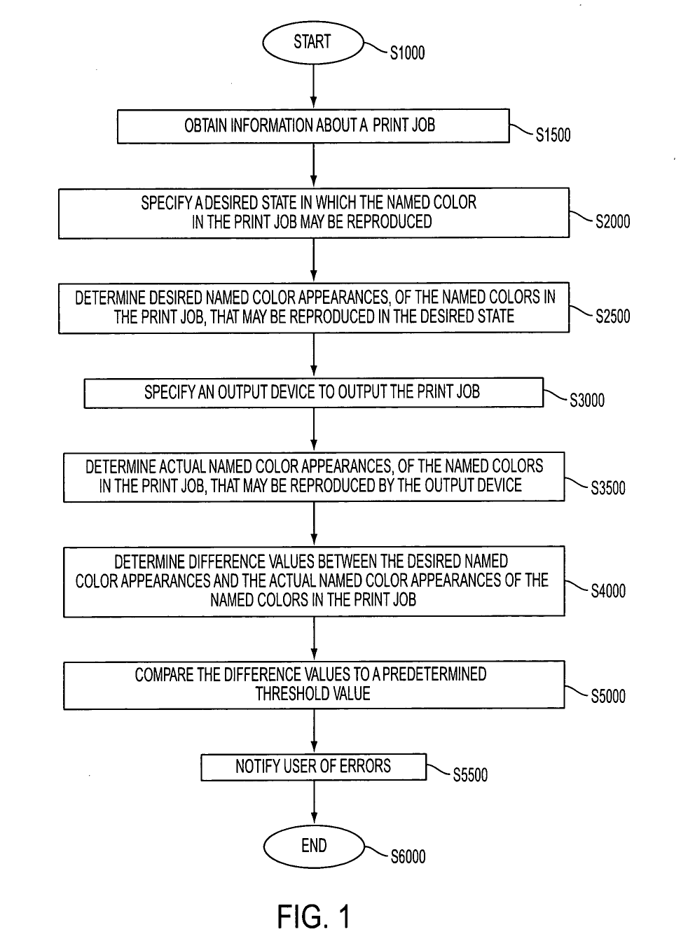

FIG. 1 is a flowchart outlining an exemplary method of evaluating colors. As shown in FIG. 1, operation of the method begins in step S1000 and continues to step S1500, in which information about a print job may be obtained. The information of the print job may include at least one of a plurality of named color. Then, in step S2000, a desired state, in which the named colors in the print job may be reproduced, may be specified by any user associated with creating or evaluating the named color, such as, for example, designers, printers and the like.

The desired state for printing the named colors may include an ideal device. The ideal device may include a press used to print Pantone® Matching System swatch books. Alternatively, the ideal device may include another device in a print shop, such as a press that will eventually be used to print the final print run in which an output device may be a proof printer used to create a contract proof.

Next, in step S2500, desired named color appearances, of the named colors that may be reproduced in the desired state, may be determined. Then, in step S3000, an output device capable of outputting the print job may be specified. Next, actual named color appearances, of the named colors that may be reproduced by the output device, may be determined in step S3500.

Then, in step S4000, difference values between the desired named color appearances and the actual named color appearances of the named colors in the print job may be determined. Next, in step S5000, the difference values may be compared to a predetermined threshold value. Then, in step S5500, the user may be notified of any spot color differences exceeding the threshold. Operation then continues to step S6000, in which the method ends.

It should be appreciated that the print job information may be obtained from any known or later developed source capable of providing a print job that may be reproduced. It should also be appreciated that the desired state and the output device may be specified by any person associated with creating or evaluating a print job.

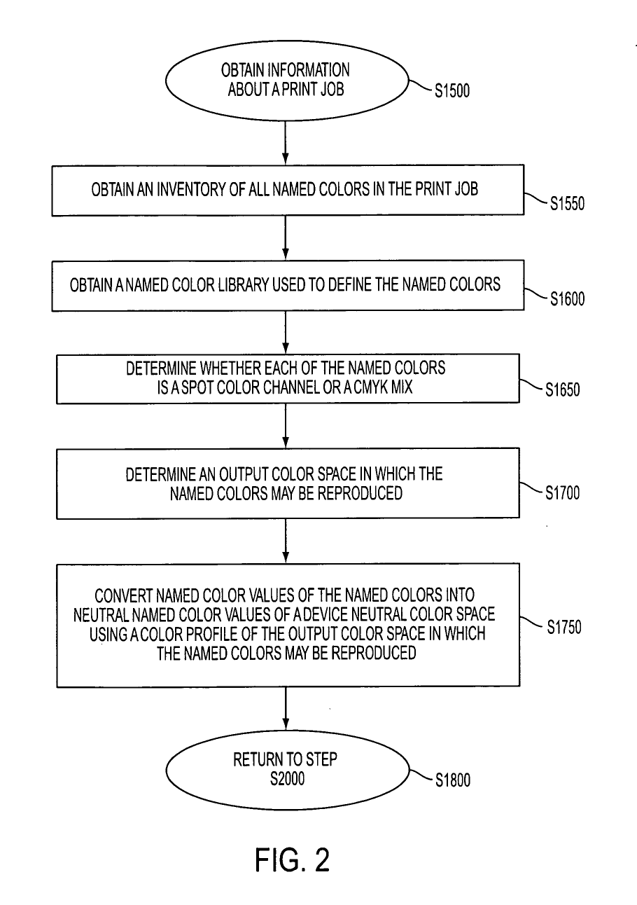

FIG. 2 is a flowchart outlining in greater detail an exemplary method of obtaining information about a print job. As shown in FIG. 2, operation of the method continues from step S1500 to step S1550, in which an inventory, of all named colors in the print job, may be obtained. The inventory may be included in an Adobe® PDF file of the print job. Next, in step S1600, a named color library used to define the named colors may be obtained. The named color library may include any library, such as a Pantone® Matching System Uncoated, Pantone® Matching System Coated, FOGRA® and the like, used to define the named colors. Then, in step S1650, a determination may be made whether each of the named colors may be defined as a spot color channel or a cyan (C), magenta (M), yellow (Y) and black (K) mix. Next, in step S1700, an output color space in which the named colors may be reproduced may be determined. For example, the output color space may include a SWOP® color space or custom CMYK color space. Operation then continues to step S1750.

As discussed above, reproducibility of spot color channels in a different color space may be problematic. Therefore, the following description is directed to spot color channels of the named colors. However, it should be appreciated that the following description may also apply to all named colors, for example, named colors including the CMYK mix. In step S1500, named color values of the named colors may be converted into neutral named color values of a device neutral color space using a color profile of the output color space in which the named colors may be reproduced. Operation of then continues to step S1800, in which operation returns to step S2000.

By using an ICC profile for an input that may be converted from an input color space to a profile connection space (PCS), named color values may be determined for each of the spot color channels in the print job. For example, in FIG. 2, the print job may include an input Adobe® PDF file containing content of an input color space, such as a standard red, green and blue (sRGB). However, to execute the print job in an output device, the named colors in the print job must be converted by using a profile for the print job that may convert the named colors from the input color space to the PCS. Therefore, an output color space in which the spot color channels may be reproduced may be determined. Subsequently, named color values associated with the spot color channels may be converted into named color PCS values using a Color Space ICC profile for the output color space.

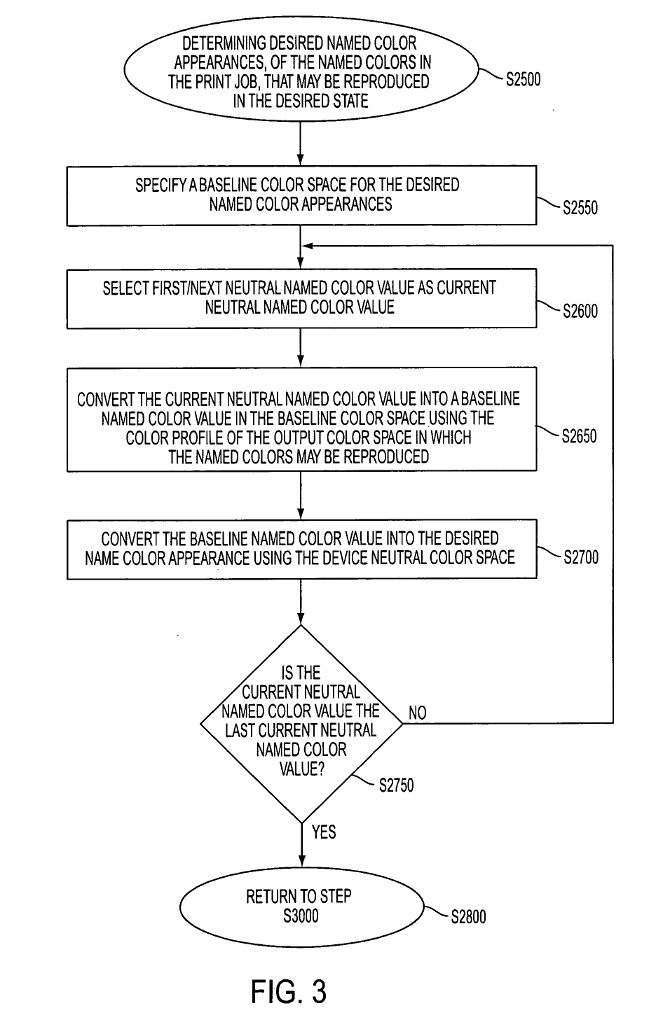

FIG. 3 is a flowchart outlining in greater detail an exemplary method of determining desired named color appearances, of the named colors in the print job, that may be reproduced in the desired state. As shown in FIG. 3, operation of the method continues from step S2500 to step S2550, in which a baseline color space for the named color appearances may be specified. A user may specify any desired color space to use as the baseline color space for the spot color channels. The baseline color space may include any of the following: a standard color space, such as SWOP®, FOGRA® and the like, using a Color Space ICC Profile; colors printed using inks, for example, Pantone®, in separations/plates using a Named Color Profile, and using a Color Space ICC Profile; colors as printed on a specific output device, for example, iGen3®, using a Device ICC Profile.

Next, in step S2600, a first or next neutral named color value may be selected as the current neutral named color value. For example, the neutral named color value may be, for example, a PCS value of the named color. Then, in step S2650, the current neutral named color value may be converted into a baseline named color value in the baseline color space, using the color profile of the output color space in which the named colors may be reproduced. For example, the named color PCS value may be converted into a color value in the baseline color space using the corresponding ICC Profile of the output color space in which the named colors may be reproduced. However, this conversion may result in color shifts due to gamut mismatches between the larger PCS color space and the smaller baseline color space.

Therefore, in step S2700, the baseline named color value may be converted into the desired named color appearance using the device neutral color space. For example, the converted baseline named color value may be converted back to the named PCS color value. Because the PCS color space is a larger color space than the baseline color space, at least some of the newly converted named PCS color values are likely to differ from the named PCS colors values of the output color space due to gamut contraction between the larger PCS color space and the smaller baseline color space.

Next, in step S2750, a determination may be made whether the current neutral named color value is the last current neutral named color value. If not, operation returns to step S2600. Otherwise, operation continues to step S2800, in which operation returns to step S3000.

At this point, desired values of the desired named color appearances of the named colors in the print job have been determined. The desired named color appearances may be an actual output from a desired device. Further, deviance of actual named color appearances in the print job that may be reproduced by a specified output device may be evaluated against these desired colors.

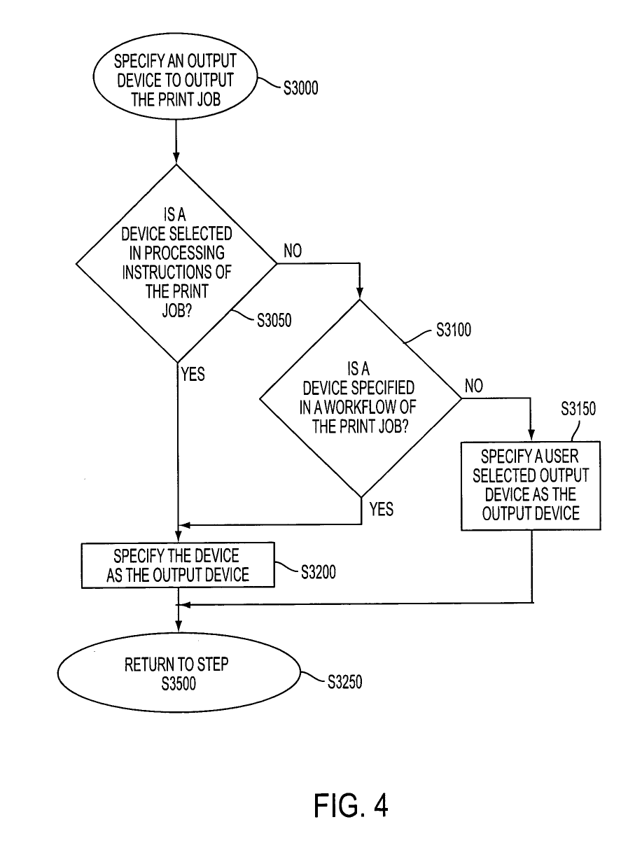

FIG. 4 is a flowchart outlining in greater detail an exemplary method of specifying an output device to output the print job. This information may come from a number of sources. As shown in FIG. 4, operation of the method continues from step S3000 to step S3050, in which a determination may be made whether a device for outputting the print job has been selected in processing instructions of the print job. If so, operation jumps to step S3200. Otherwise, operation continues to step S3100.

In step S3100, a determination may be made whether a device for outputting the print job has been selected in a workflow of the print job. If so, operation jumps to step S3200. Otherwise, operation continues to step S3150.

In step S3200, the selected device may be specified as the output device. Operation then jumps to step S3250. In contrast, in step S3150, a user selected output device may be specified as the output device. Operation then continues to step S3250, in which operation returns to step S3500.

Although the above description is directed towards specifying an output device, it should be appreciated that specifying the output device may include specifying a desired output raster image processor (RIP) and an output print engine for outputting the print job. For example, exemplary methods and systems may include evaluating a current print job's processing instructions and ascertaining if the RIP and the print engine are specified in the current print job's ticket. If so, then the system/method may use the information for that device. Otherwise, the system/method may evaluate the current workflow or process plan to determine if there is an output operation. If the output operation specifies a RIP and a print engine pair, the system/method may use the information for that RIP and that device. Finally, the system/method may allow the user to specify a default RIP and SWOP® as the default output color space of a default print engine if there is none specified in either the current job's processing instructions or workflow.

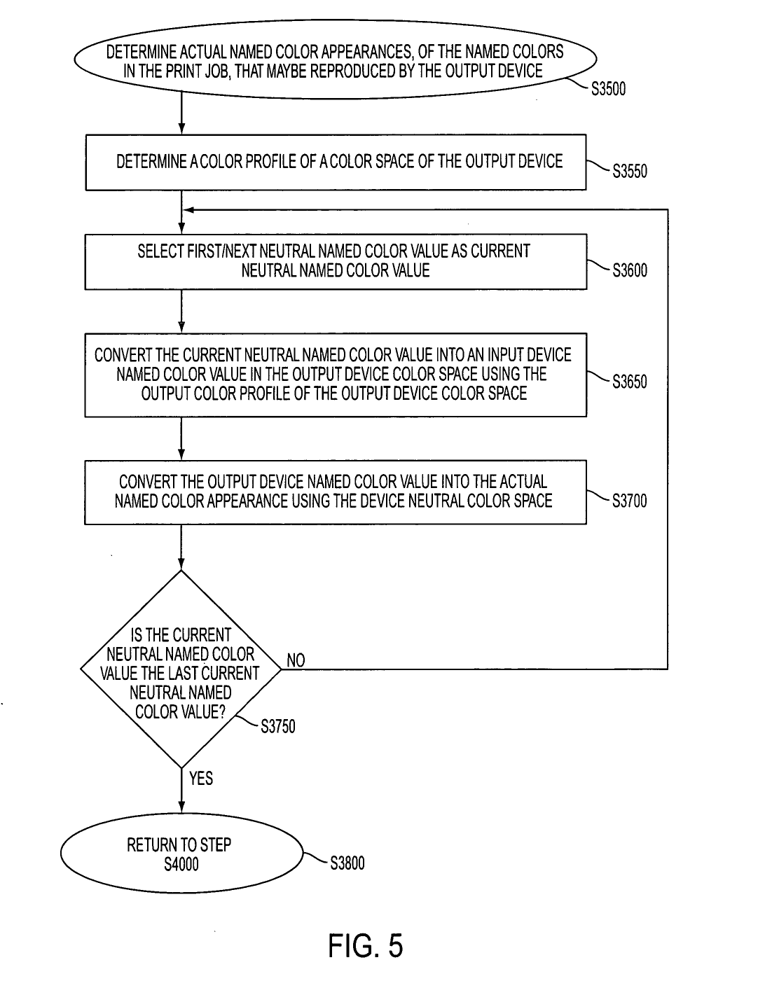

FIG. 5 is a flowchart outlining in greater detail an exemplary method of determining actual named color appearances, of the named colors in the print job, that may be reproduced by the output device. As shown in FIG. 5, operation of the method continues from step S3500 to step S3550, in which a color profile of a color space of the output device may be determined.

Next, in step S3600, a first or next neutral named color value may be selected as the current neutral named color value. For example, the neutral named color value may be, for example, a PCS value of the named color. Then, in step S3650, the current neutral named color value may be converted into an output device named color value in the output device color space, using the color profile of the output device color space. For example, when the output device is known, the named color PCS value may be converted to color value in output device color space using the corresponding Device ICC Profile and the rendering intent specified for the object whose color is being evaluated. However, this conversion may occur as part of a normal printing operation, and may result in color shifts due to gamut mismatches between the larger PCS color space and the smaller output device color space.

Therefore, in step S3700, the device named color value may be converted into the actual named color appearance using the device neutral color space. For example, the converted output device named color value may be converted back to the named PCS color value using the absolute calorimetric rendering intent data of the ICC Device Profile. At least some of the newly converted named PCS color values are likely to differ from the named PCS colors values of the output color space due to gamut contraction between the larger baseline color space and the smaller output device color space and any color shifting induced by the gamut mapping behavior of the rendering intent.

Next, in step S3750, a determination may be made whether the current neutral named color value is the last current neutral named color value. If not, operation returns to step S3600. Otherwise, operation continues to step S3800, in which operation returns to step S4000.

At this point, actual values of the actual named color appearances of the named colors in the print job have been determined. The actual named color appearances may be an actual output from the output device. Because the desired named color appearance and the actual named color appearance have been determined as PCS color values for all named colors in the print job, a deviance of actual named color appearances in the print job that may be reproduced by a specified output device may be evaluated against the desired named color appearances.

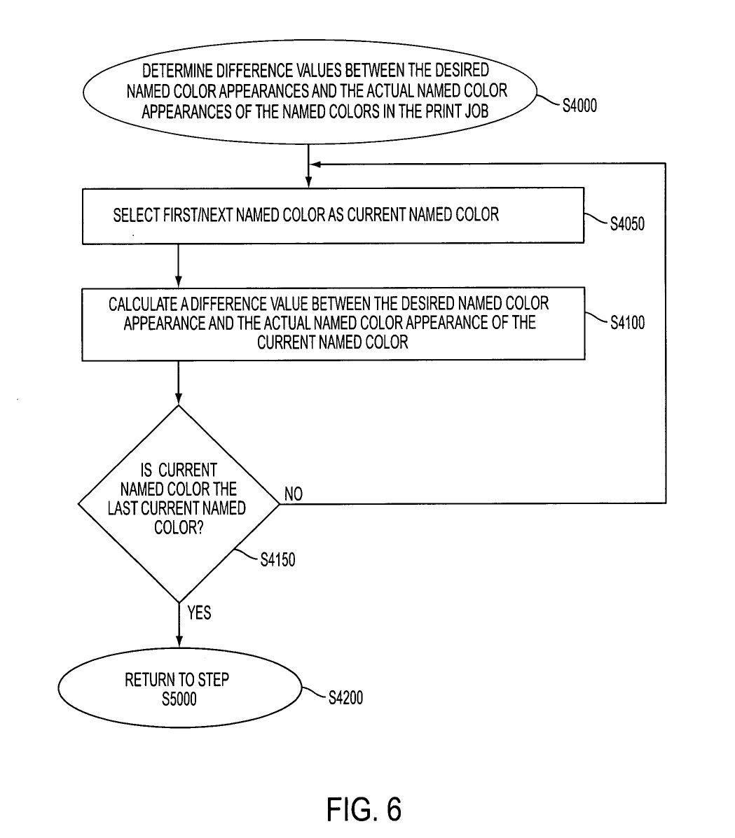

FIG. 6 is a flowchart outlining in greater detail an exemplary method of determining a difference value between the desired named color appearance and the actual named color appearance of the named color in the print job. As shown in FIG. 6, operation of the method continues from step S4000 to step S4050, in which a first or next named color value may be selected as the current named color. Then, in step S4100, a difference value may be calculated between the desired named color appearance and the actual named color appearance of the current named color. Next, in step S4150, a determination may be made whether the current named is the last current named color. If not, operation returns to step S4050. Otherwise, operation continues to step S4200, in which operation returns to step S5000.

Subsequently, all named colors for both the desired color space and the actual color space may be compared to a threshold value using any number of readily available methods, for example, delta E, Euclidean distance, and the like. The user or a default setting on an exemplary system, may set a threshold value to determine whether or not the named colors in the print job diverge too much between output devices for an accurate reproduction. For example, any pair of named colors with a deviance greater than a user defined threshold value may cause the print job to fault and may also prompt the user for manual intervention.

If the specified reproduction deviation value is outside the user-defined deviance threshold/tolerance, an error may be flagged. When all named colors have been evaluated, the users may be warned about flagged errors, if any. Optionally, the exemplary system may display the deviating spot color channels may be displayed on a display screen or included in a printed report. Optionally, similar alternate colors that do not violate the deviation threshold may be suggested.

The exemplary embodiment described above involves evaluating named colors against print engine gamuts. However, other exemplary embodiment may involve evaluating named colors against predetermined colors, for example, colors located in a spot color lookup table of a print engine.

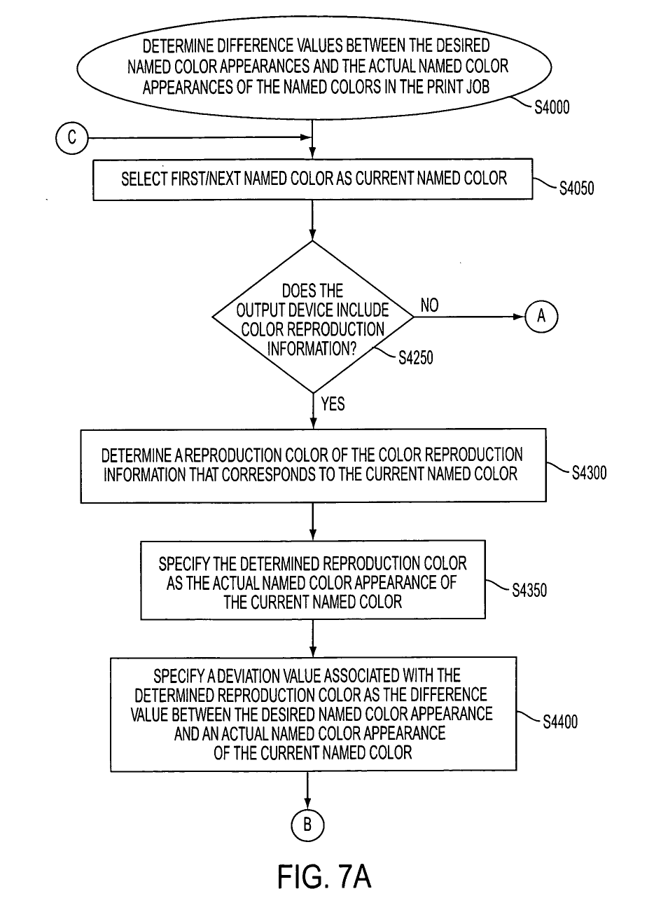

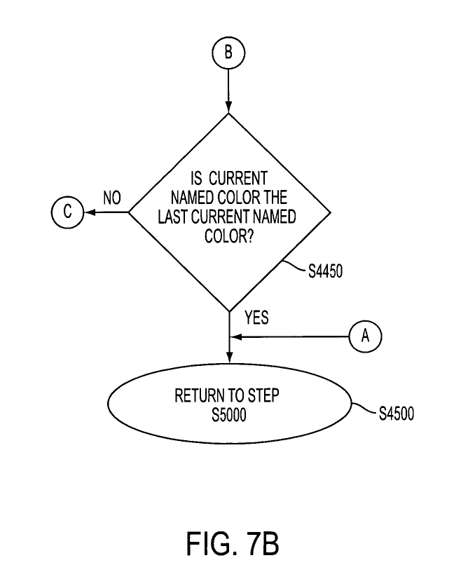

In the exemplary embodiment of FIG. 7, a method of evaluating colors may involve substantially similar steps as discussed above with respect to FIGS. 1 and 2. For example, information about a print job may be gathered to specify an Adobe® PDF file that may be evaluated by making an inventory of all named colors, determining the named color library used to define the named colors, and determining whether the named color is defined as a spot color channel or a CMYK mix. Further, an output device may be specified, as discussed above with respect to FIG. 4. For example, a desired output RIP and a print engine may be determined for the print job.

However, it is not necessary to convert named color values as in step S1750. Additionally, the desired state in step S2000 maybe previously specified and/or incorporated into the color reproduction information of the output device. Further, the desired named color appearances in step S2500 may also be previously specified and/or incorporated into the color reproduction information of the output device. Finally, the actual named color appearances in step S3500 may be determined as part of determining the difference values in step S4000.

The flowchart of FIG. 7 outlines in greater detail an exemplary method of determining difference values between the desired named color appearance and the actual named color appearance of the named color in the print job. As shown in FIG. 7, operation of the method continues from step S4000 to step S4050, in which a first or next named color may be selected as the current named color, as described above with respect to FIG. 6. However, the remaining steps included in determining difference values differ from the steps of FIG. 6.

Next, in step S4250, a determination may be made whether the output device includes color reproduction information. If so, operation continues to step S4300. Otherwise, operation jumps to step S4500.

In step S4300, a reproduction color, of the color reproduction information, that corresponds to the current named color may be determined. The reproduction color will include the gamut mapping effect of the rendering intent. Then, the determined reproduction color may be specified as the actual named color appearance of the current named color in step S4350. Next, in step S4400, a deviation value associated with the determined reproduction color may be specified as the difference value between the desired named color appearance and the actual named color appearance of the current named color.

Then, in step S4450, a determination may be made whether the current named color is the last current named color. If so, operation jumps to step S4050. Otherwise, operation continues to step S4500, in which operation returns to step S5000.

It should be appreciated that the color reproduction information of a specified output device may be located in a lookup table. As a result, a determination may be whether or not a specified print engine contains a lookup table, for example, color reproduction information, for a named color library. The color reproduction information may be obtained as part of a color certification, for example, Pantone® Matching System certification, received by the specified RIP and print engine pair.

If no lookup table exists, there is no color reproduction information to compare against the named spot color channels. As a result, the system may either ignore the named spot color channel or flag an error based on a user specified preference. If the lookup table exists, a reproduction deviation specified in the color reproduction information may be compare against a reproduction deviance value, for example, a threshold or tolerance. The reproduction deviation value refers to an amount of deviation of the spot color channel reproduction by the specified print engine from a specific color reference, for example, Pantone® Matching System.

As a result, the named spot color channel values may be located in the lookup table of the print engine to determine a corresponding reproduction deviation value from the ideal Pantone® Matching System colors. The reproduction deviation value may then be compared to a user-define tolerance or a tolerance configured in a system as some kind of default threshold. Therefore, a Pantone® Matching System coded lookup table may reveal that the print engine reproduction spot color channel may deviate 2ΔE from an ideal spot color channel. Finally, a determination may be made whether the reproduction deviance value is outside the defined tolerance.

For example, print engines may receive Pantone® Matching System certification certifying that the specified print engine may produce all the Pantone® Matching System colors within a certain tolerance. The certification of the RIP and print engine pair may include measuring the deviation of spot color channels that may be reproduced by the print engine from the ideal Pantone® Matching System colors. Further, a lookup table including color reproduction information for all spot color channels may be produced and may be associated with the RIP of the print engine. Therefore, the lookup table may include information for all the Pantone® Matching System coded spot colors.

If the named spot colors in a Adobe® PDF file of a print job includes Pantone® 320 and Pantone® 185, the lookup table may reveal the deviance for the Pantone® 320 from to an ideal Pantone® 320 if the named spot color is reproduced by the print engine. The deviance may be compared to a user-define threshold value to determine if the user should be warned that the named spot color may not be sufficiently reproduced by the print engine.

Exemplary embodiments for evaluating named colors against specified print engines may be used in either offset reprint or proofing workflows.

When the exemplary embodiments are used in reprinting offset files at the end of a job life cycle, post-RIP colors from print engines may be evaluated against colors from offset color spaces such as SWOP or specific spot color inks used in offset printing. Offset reprint means that, if there are very large runs in the life cycle of a document, the run may be printed on an offset press that may use primary CMYK inks and spot colors. Alternatively, the run may be printed on a xerographic device. If the exemplary system/method determines that the named spot colors may be sufficiently reproduced without substantial deviation from a defined threshold value, the job may be processed without further operator review or intervention. However, if the exemplary system/method determines that the named spot colors may be reproduced with a substantial difference, the job may be routed for further operator review or intervention.

When the exemplary embodiments are used in a proofing workflows at the beginning of a job life cycle, a determination of how the named colors may print in the proofing device may be compared to a determination of how the named colors would print in a final output device. In proofing workflows, the goal is to automatically flag proofs that are not representative of how the job will print in the final output device because of differences in how the proofing device and the final output device may print named colors. By flagging specific problematic jobs, the system/method may be more efficient than the conventional approach of a first device printing color swatches for customers to view the swatches and hope that the customer's device will print colors substantially identical to the swatches.

FIG. 9 is a block diagram outlining an exemplary system for evaluating colors. As shown in FIG. 9, the system 7000 may include a print job source 7050, a desired state determining device 7100, a desired named color appearance determining device 7150, an output specifying device 7200, an actual named color appearance determining device 7250, a difference value determining device 7300, an input output device 7350, a controller 7400, a memory 7450, each appropriately connected by one or more control and/or data buses 7500. The system 7000 may also include a display device 8000, appropriately connected by the one or more control and/or data buses 7500.

The print job source 7050 may be any document source such as a scanner, multifunctional device, or any other known or hereafter developed device capable of providing information of a print job. Alternatively, the print job source may be located externally of the system 7000, and input print jobs via the input/output device 7350 to the system 7000.

The desired state determining device 7100 be any device such as a computer system, a processor or other device capable of identifying a user-specified or default desired state. Although this device is described as a separate device, it should be appreciated that this device may be a part of any type of general purpose computer or device capable of identifying a desires state or an output device or handling other types of processing.

The desired named color appearance determining device 7150, the actual named color appearance determining device 7250, and the difference value determining device 7300 each may be any device such as a computer system, a processor or other device capable of obtaining, evaluating and/or converting named color information of the identified print job received from the print job source 7050. Although these devices are described as separate devices, it should be appreciated that these devices may be a part of any type of general purpose computer or device capable of manipulating data or handling other types of processing.

The output specifying device 7200 may be any device such as a computer system, a processor or other device capable of identifying a user-specified or default desired state and a user-specified or default output device. Although this device is described as a separate device, it should be appreciated that this device may be a part of any type of general purpose computer or device capable of identifying an output device or handling other types of processing.

The memory 7450 may be implemented using any appropriate combination of alterable, volatile or non-volatile memory or non-alterable, or fixed, memory. The alterable memory, whether volatile or non-volatile, may be implemented by using any one or more of static or dynamic RAM, a floppy disk and disk drive, a writeable or rewriteable optical disk and disk drive, a hard drive, flash memory or the like. Similarly, the non-alterable or fixed memory may be implemented using any one or more of ROM, PROM, EPROM, EEPROM, and gaps in optical ROM disk, such as a CD ROM or DVD ROM disk and disk drive, or the like.

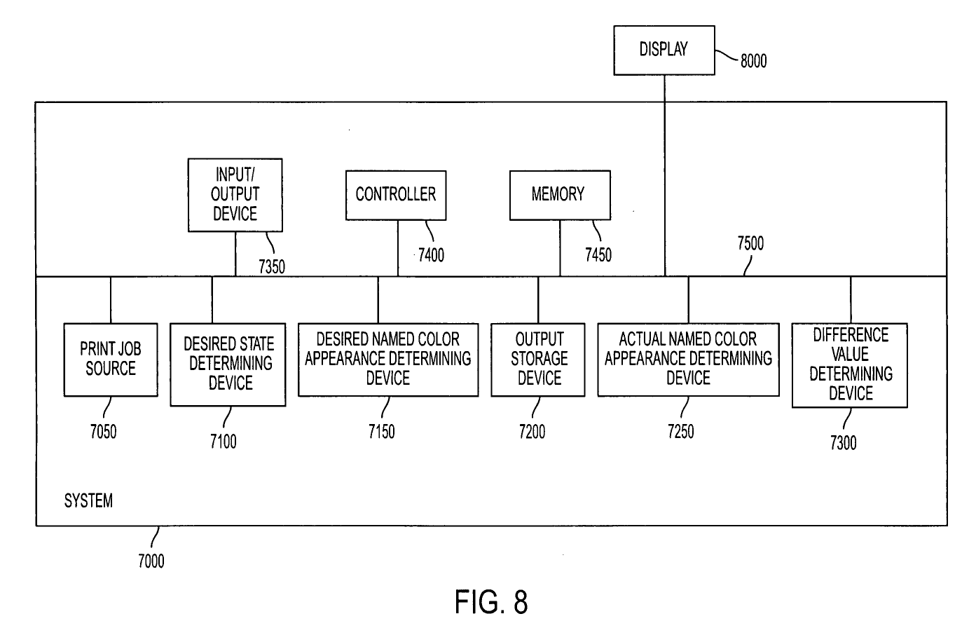

The exemplary system for evaluating colors according to FIG. 8 may operate in the following manner under the control of the controller 7400 and may store captured, received or transmitted information in the memory 7450 by using any known or later developed device or method. A user of the system may provide at least one print job to a print job source 7050. The print job may include information of at least one named color.

The desired state determining device 7100 may receive the print job and determine a desired state in which the named color in the print job may be reproduced. The desired named color appearance determining device 7150 may then determine a desired named color appearance, of the named color in the print job, that may be reproduced in the desired state.

The output specifying device 7200 may specify an output device to output the print job. The actual named color appearance determining device 7250 may then determine an actual named color appearance, of the named color in the print job, that may be reproduced by the output device.

Next, the difference value determining device 7300 may determine a difference value between the desired named color appearance and the actual named color appearance of the named color in the print job.

The exemplary system for evaluating colors may further include a comparing device that compares the difference value to a predetermined threshold value. Furthermore, the exemplary system may include a user notifying device that may send an error message through the bus 7500 to the display 8000 via the input/output device 7350. Alternatively, the user notifying device may include a printed report or an audible alarm, capable of notifying the user of a potential color reproduction error.

An exemplary system for evaluating colors may also be incorporated in a printing system including an image output device, such as a xerographic device, a monitor, and the like.

It will be appreciated that various of the above-disclosed and other features and functions, or alternatives thereof, may be desirably combined into many other different systems or applications. Also, various presently unforeseen or unanticipated alternatives, modifications, variations or improvements therein may be subsequently made by those skilled in the art which are also intended to be encompassed by the following claims.

What is claimed is:

1. A method of evaluating colors, comprising
obtaining information about a print job, the information including at least one named color;
specifying a desired state in which the named color in the print job may be reproduced;
determining a desired named color appearance, of the name color in the print job, that may be reproduced in the desired state;
specifying an output device to output the print job;
determining an actual named color appearance, of the named color in the print job, that may be reproduced by the output device; and
determining a difference value between the desired named color appearance and the actual named color appearance of the named color in the print job.

2. The method of claim 1, further comprising comparing the difference value to a predetermined threshold value, wherein determining the difference value includes determining the actual named color appearance based on at least one characteristic of the output device.

3. The method of claim 1, wherein obtaining the information about the print job includes determining an output color space in which the named color may be reproduced.

4. The method of claim 3, wherein obtaining the information about the print job further includes converting a named color value of the named color into a neutral named color value of a device neutral color space based on a color profile of the output color space in which the named color may be reproduced.

5. The method of claim 4, wherein determining the difference value between the desired named color appearance and the actual named color appearance includes determining a desired named color value of the named color and an actual named color value of the named color.

6. The method of claim 5, wherein determining the desired named color appearance includes specifying a baseline color space for the desired named color.

7. The method of claim 6, wherein determining the desired named color appearance further includes converting the neutral named color value into a baseline named color value in the baseline color space based on the color profile of the color space in which the named color may be reproduced.

8. The method of claim 4, wherein determining the actual named color appearance includes determining an output device color profile of a color space of the output device.

9. The method of claim 8, wherein determining the actual named color appearance further includes converting the neutral named color value into a output device named color value in the output device color space based on the output device color profile.

10. The method of claim 1, wherein determining the difference value between the desired named color appearance and the actual named color appearance includes calculating the difference value between the desired named color appearance of the named color and the actual named color appearance of the named color.

11. The method of claim 1, wherein determining the difference value between the desired named color appearance and the actual named color appearance includes determining color reproduction information of the output device.

12. The method of claim 11, wherein determining the color reproduction information includes determining a reproduction color that corresponds to the named color.

13. The method of claim 12, wherein determining the actual named color appearance includes specifying the reproduction color as the actual named color appearance of the named color.

14. The method of claim 13, wherein determining the difference value between the desired named color appearance and the actual named color appearance further includes specifying a deviation value associated with the reproduction color as the difference value between the desired named color appearance and the actual named color appearance.

15. The method of claim 11, wherein determining the color reproduction information of the output device includes determining an existence of a lookup table.

16. The method of claim 1, wherein obtaining the information about the print job includes obtaining an inventory of all of the named colors.

17. The method of claim 1, wherein obtaining the information about the print job includes obtaining a named color library that defines all of the named colors.

18. The method of claim 1, wherein obtaining the information about the print job includes identifying a spot color channel as the named color.

19. A system for evaluating colors, comprising:
a print job source including at least one print job, the print job including information of at least one named color;
a specified desired state determining device configured to determine a desired state in which the named color in the print job may be reproduced;
a desired named color appearance determining device configured to determine a desired named color appearance, of the named color in the print job, that may be reproduced in the desired state;
an output specifying device configured to specify an output device to output the print job;
an actual named color appearance determining device configured to determine an actual named color appearance, of the named color in the print job, that may be reproduced by the output device; and
a difference value determining device configured to determine a difference value between the desired named color appearance and the actual named color appearance of the named color in the print job.

20. A printing system comprising image output device and the system of claim 19.
